(19) United States
(12) Patent Application Publication
(10) Pub. No.: US 2008/0055126 A1
(43) Pub. Date: Mar. 6, 2008

(54) PARALLELIZATION OF SERIAL DIGITAL INPUT SIGNALS

(75) Inventors: Chaitanya Dudha, Muenchen (DE); Tim Schoenauer, Feldkirchen (DE); Paul Wallner, Prien (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignees: Qimonda AG, Muenchen (DE); Infineon Technologies AG, Neubiberg (DE)

(21) Appl. No.: 11/851,129

(22) Filed: Sep. 6, 2007

(30) Foreign Application Priority Data
Sep. 6, 2006 (DE) 10 2006 041 785.2

(51) Int. Cl. H03M 9/00

(52) U.S. Cl. 341/100

(57) ABSTRACT

A device configured to parallelize N serial digital input signals includes at least M bit storage devices configured to each respectively store one bit of the N serial digital input signals and provide the one stored bit as a bit of a parallel digital output signal with a bit width M. M is greater than N and N is greater than 1. Symbols with a bit width M are transmitted via the N serial digital input signals such that each of the N serial digital input signals transmits a fraction of the respective symbol. A control device is configured to drive the plurality of bit storage devices cyclically such that at least M bits of the serial digital input signals, which belong to one symbol, are stored in the bit storage devices within a cycle.

### CROSS-REFERENCE TO RELATED APPLICATIONS

This Utility Patent Application claims priority to German Patent Application No. DE 10 2006 041 785.2, filed on Sep. 6, 2006, which is incorporated herein by reference.

### BACKGROUND

The present disclosure relates to devices and methods for the parallelization of serial digital input signals to form a parallel digital output signal.

### SUMMARY

One embodiment of a device is configured to parallelize N serial digital input signals. The device includes at least M bit storage devices configured to each respectively store one bit of the N serial digital input signals and provide the one stored bit as a bit of a parallel digital output signal with a bit width M. M is greater than N and N is greater than 1. Symbols with a bit width M are transmitted via the N serial digital input signals such that each of the N serial digital input signals transmits a fraction of the respective symbol. The device includes a control device configured to drive the plurality of bit storage devices cyclically such that at least M bits of the serial digital input signals, which belong to one symbol, are stored in the bit storage devices within a cycle.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates schematically an embodiment of a device for the parallelization of four serial digital input signals to form a parallel digital output signal.

FIG. 2 illustrates an example time control profile of input and output signals of the device of FIG. 1.

FIG. 3 illustrates an embodiment of a device for the parallelization of four serial digital input signals to form a parallel digital output signal having a bit width of 9.

FIG. 4 illustrates an embodiment of the device in FIG. 3 with a control device.

FIG. 5 illustrates an example time control profile of the embodiment of the device illustrated in FIG. 4.

FIG. 6 illustrates an embodiment of a control device of the device of FIG. 3.

FIG. 7 illustrates an example time control profile of the embodiment illustrated in FIG. 6.

FIG. 8A illustrates an embodiment of a control device of the device of FIG. 3.

FIG. 8B illustrates an example time control profile of the embodiment illustrated in FIG. 8A.

FIG. 9A illustrates an embodiment of a control device of the device of FIG. 3.

FIG. 9B illustrates an example time control profile of the embodiment illustrated in FIG. 9A.

FIG. 10A and FIG. 10B respectively illustrate two embodiments of a clock switching device of the device of FIG. 3.

FIG. 11A illustrates an embodiment of a control device of the device of FIG. 3.

FIGS. 11B and 11C illustrate an example time control profile of the device illustrated in FIG. 11A.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

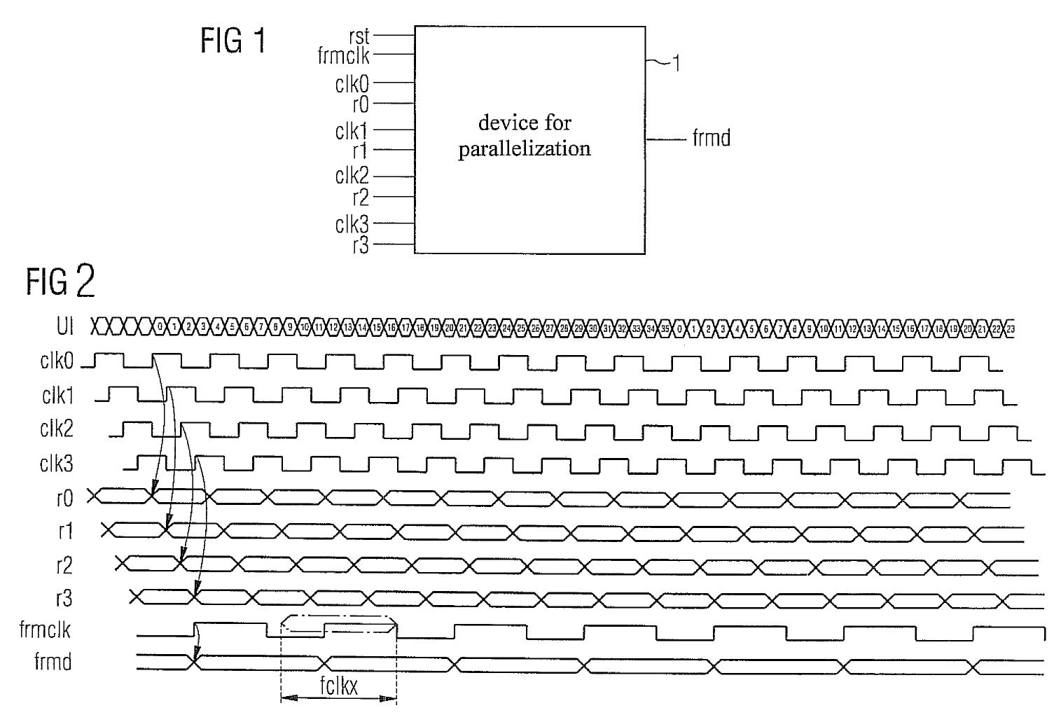

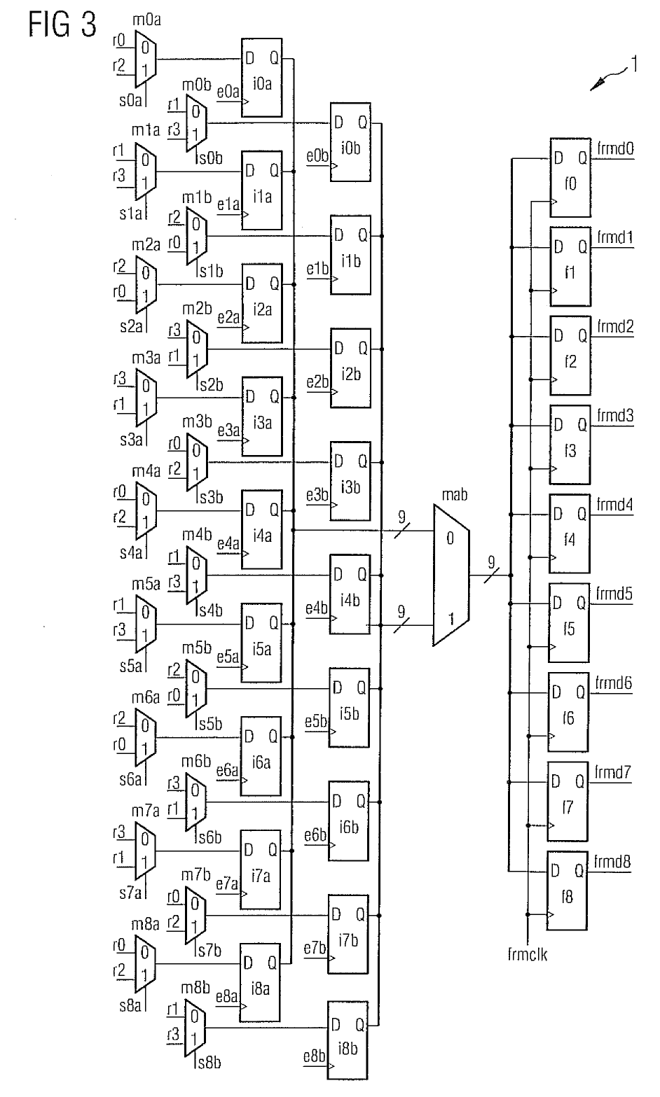

The functionality of an embodiment of a device for parallelization of a serial digital input signal to form a parallel digital output signal is described in the following from an external view of the device with reference to FIGS. 1 and 2. In this embodiment, symbols comprising 9 bits each are transmitted via four data lines. Therefore, the device is adapted to generate a parallel 9 bit wide data stream from the four data lines comprising the serial data stream. The serial data are transmitted with the same clock frequency but with a different phase angle on the individual data lines. The phase angles of the four serial data transmission lines are respectively phase-shifted by 90° relative to each other.

FIG. 1 illustrates a serial-to-parallel converter 1 with four input clock signals clk0-clk3, four serial data input signals r0-r3 allocated to the individual input clock signals, a 9-bit wide parallel data output signal frmd, an output data clock, and a reset input rst for the serial-to-parallel converter 1.

FIG. 2 represents corresponding signal level profiles of serial-to-parallel converter 1. A first 9-bit wide symbol is transmitted via the four serial input signals in such a way that bit 0 of the symbol is transmitted via a first input signal r0, bit 1 of the symbol is transmitted via a second input signal r1, bit 2 of the symbol is transmitted via a third input signal r2, and bit 3 of the symbol is transmitted via a fourth input signal r3. Subsequently, bit 4 of the symbol is transmitted via the first input signal r0, bit 5 of the symbol is transmitted via the second input signal r1, bit 6 of the symbol is transmitted via the third input signal r2, and bit 7 of the symbol is transmitted via the fourth input signal r3. After this, bit 8 of the symbol is transmitted via the first input signal r0. This concludes the transmission of the first symbol. A transmission of a second symbol begins by transmitting bit 0 of the symbol via the second input signal r1, transmitting bit 1 of the symbol via the third input signal r2, and transmitting bit 2 of the symbol via the fourth input signal r3. This method is continued until a fourth signal is fully transmitted, where bit 8 of the fourth symbol is transmitted via the fourth input signal r3. In this way, a total of 36 bits of four symbols are transmitted and a complete cycle is concluded, so that transmission of a fifth symbol is carried out similarly as the transmission of the first symbol. FIG. 2 illustrates the transmission of such a cycle, in which 36 bits are transmitted in the 36 intervals UI0-UI35.

The input signals r0-r3 respectively have their own clock clk0-clk3, the clock signals clk0-clk3 allocated to the individual input signals being phase-shifted respectively by 90° to one another. As represented by the arrows between the clock signals clk0-clk3 and the data signals r0-r3, the data transfer is carried out with the rising edge of the respective clock signal. The parallelized data output signal frmd is provided with the rising edge of the clock signal frmclk at the outputs frmd, as represented in FIG. 2 by the arrow between the output data clock frmclk and the output signal frmd. Since the clock signal frmclk is generated by a postprocessing device (not illustrated), for example a memory arrangement, the output clock signal frmclk is only synchronized with the input clock signals clk0-clk3 via a relatively large phase offset with a width of, for example eight intervals, as represented by fclkx in FIG. 2. A maximally wide range, in which the rising edge of the output clock signal can be delivered to the serial-to-parallel converter 1, is therefore particularly desirable. An example of such a desirable range for the rising clock edge of the output clock signal is the region denoted by fclkx in FIG. 2.

Although many of embodiments are adapted to perform a parallelization of four serial input signals to form a nine bit wide parallel output signal, embodiments are not restricted to this kind of parallelization.

Embodiments include a device and a method for the parallelization of a plurality of serial digital input signals to form a parallel digital output signal. The number of serial digital input signals is at least two, and is denoted below by N. The bit width of the digital output signal is greater than N, and is denoted below by M. Via the N serial digital input signals, symbols with a bit width M are transmitted in such a way that each of the N serial digital input signals transmits a fraction of the respective symbol.

A method according to an embodiment comprises delivery of the serial digital input signals to at least M bit storage devices, each bit storage device being respectively configured for storing one bit of the N serial digital input signals and being allocated to precisely one bit position of the symbol, cyclic controlling of the at least M bit storage devices, where controlling one of the at least M bit storage devices causes a data bit, which is delivered to the respective bit storage device, to be stored in the respective bit storage device in such a way that at least M bits of the serial digital input signals, which belong to a symbol, are stored in the at least M bit storage devices within a cycle, and reading out of the at least M bit storage devices in order to provide a signal with the bit width M on the output signal.

A device according to an embodiment comprises a plurality of bit storage devices which are respectively configured for storing one bit of the serial digital input signals. The bit stored by each bit storage device is output as a bit of the parallel output signal. The number of bit storage devices is at least M. The device embodiment comprises a control device for controlling the bit storage devices, which drives the bit storage devices cyclically in such a way that at least M bits of the serial digital input signals, which belong to a symbol, are stored in the bit storage devices within a cycle.

The device according to this embodiment employs very few gate functions and therefore uses only little area and energy on a semiconductor chip. This device furthermore has an extremely short delay time between the arrival of the serial digital input signals and output of the parallelized digital output signal, because the parallel digital output signal is available for postprocessing immediately after storage of the last bit of a symbol.

According to an embodiment, the control device comprises one or more looped shift register arrangements. Each looped shift register arrangement comprises a plurality of shift register bit storage devices connected in a ring.

Using a shift register arrangement for driving the bit storage devices achieves a high level of robustness of the circuit, because only few signals change their state at each change of state inside the control device.

In an embodiment, the device is configured in such a way that precisely one bit position of the symbol is allocated to each of the bit storage devices, and the device additionally comprises a plurality of multiplex devices which are respectively coupled on the input side to a plurality of the N serial digital input signals and are respectively coupled on the output side to an input of at least one of the bit storage devices. The multiplex devices can therefore connect the respective bit storage devices in a controlled way as a function of time to the serial digital input signals, which transmit data bits for the bit position of the respective bit storage device. The control device is in this case additionally configured for driving the plurality of multiplex devices.

Such an embodiment of the device is particularly applicable when M is not a multiple of N, since the number of bit storage devices can then be reduced considerably, for example even to M. This allows a considerable saving on gate functions and therefore chip area and power consumption.

According to an embodiment, the number N of serial digital input signals is an even number. The N serial digital input signals have the same clock frequency and a different clock phase angle. The clock phase angles of the N serial digital input signals are respectively shifted approximately by 360°/N relative to one another. The control device comprises N/2 looped shift register arrangements. Each of these looped shift register arrangements has an even number of shift register bit storage devices. The shift register bit storage devices are driven alternately with clocks phase-shifted by 180°. A bit pattern which comprises a plurality of bit segments is shifted continuously in the looped shift register arrangement, the bit segments alternately having a first logical value and a second logical value different therefrom. The shift register bit storage devices of the first looped shift register arrangement are driven with clocks having a phase angle of 0° and 180°. The shift register bit storage devices of the second looped shift register arrangement are driven with clocks having a phase angle of 360°/N and 180°+360°/N. The shift register bit storage devices of the third looped shift register arrangement are driven with clocks having a phase angle of 2*360°/N and 180°+2*360°/N, etc.

A configuration of the control device according to the previously described embodiment employs only few shift register bit storage devices for driving the bit storage devices. Furthermore, only few signals inside the control device change at each change of state of the control device, so that the robustness of the control device is increased.

Hereinafter, embodiments are described in more detail with reference to the drawings.

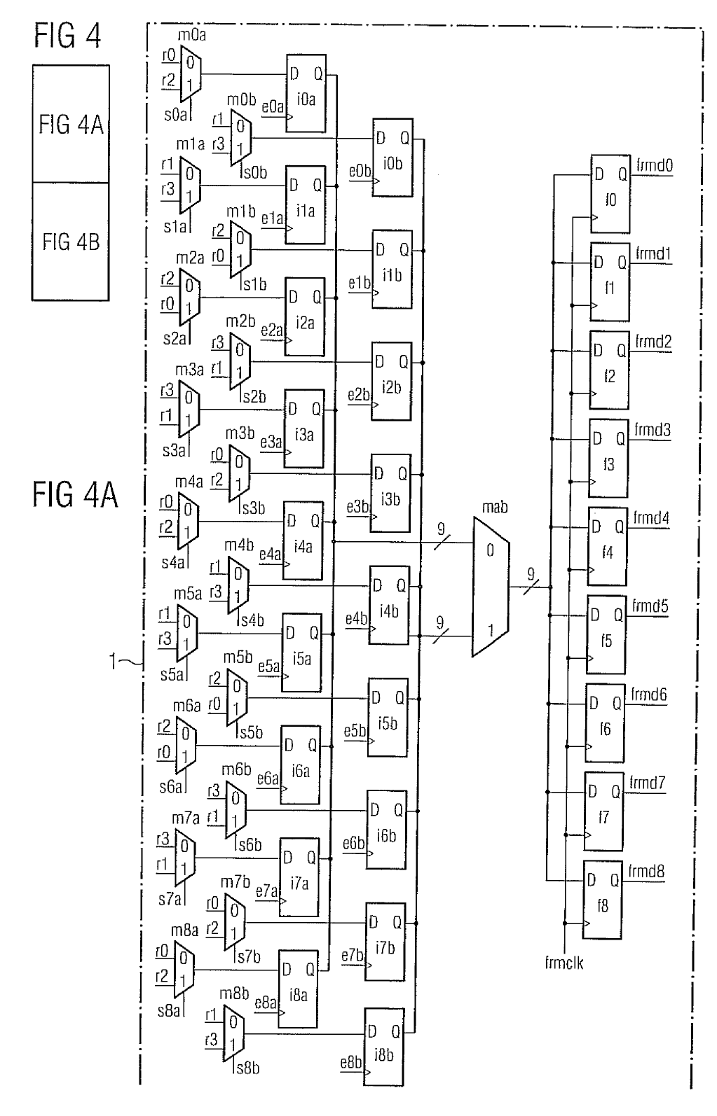

FIG. 3 illustrates a device 1 according to an embodiment for the parallelization of four serial digital input signals r0-r3 to form a parallel digital output signal frmd0-frmd8. The device 1 comprises 18 bit storage devices i0a-i8a and i0b-i8b, a multiplex device mab, nine output bit storage devices f0-f8 and 18 multiplex devices m0a-m8a and m0b-m8b. The outputs of the multiplex devices m0a-m8a and m0b-m8b are connected to the inputs D of the bit storage devices i0a-i8a and i0b-i8b, in such a way that the output of the multiplex device m0a is connected to the input D of the bit storage device i0a, the output of the multiplex device m1a is connected to the input D of the bit storage device i1a, etc. The outputs Q of the bit storage devices i0a-i8a and i0b-i8b are connected to 18 inputs of the multiplex device mab. The nine outputs of the multiplex device mab are respectively connected to an input of the nine output bit storage devices f0-f8. The parallelized digital output signals with a bit width of nine are provided at the outputs Q of the output bit storage devices f0-f8 and can be forwarded via the signal lines frmd0-frmd8 to postprocessing devices (not illustrated).

A control device (described below) of the device 1 drives the multiplex devices m0a-m8a via the control lines s0a-s8a, the multiplex devices m0b-m8b via the control lines s0b-s8b, the bit storage devices i0a-i8a via the control lines e0a-e8a, and the bit storage devices i0b-i8b via the control lines e0b-e8b, as described below.

Transmission of a first 9-bit wide symbol via the four serial input signals r0-r3 is carried out in such a way that bit 0 of the symbol is transmitted via a first input signal r0, bit 1 of the symbol is transmitted via a second input signal r1, bit 2 of the symbol is transmitted via a third input signal r2, and bit 3 of the symbol is transmitted via a fourth input signal r3. Subsequently, bit 4 of the symbol is transmitted via the first input signal r0, bit 5 of the symbol is transmitted via the second input signal r1, bit 6 of the symbol is transmitted via the third input signal r2, and bit 7 of the symbol is transmitted via the fourth input signal r3. After this, bit 8 of the symbol is transmitted via the first input signal r0. This concludes the transmission of the first symbol. The transmission of a second symbol begins by transmitting bit 0 of the symbol via the second input signal r1, transmitting bit 1 of the symbol via the third input signal r2, and transmitting bit 2 of the symbol via the fourth input signal r3. This method is continued until a fourth signal is fully transmitted, where bit 8 of the fourth symbol is transmitted via the fourth input signal r3. In this way, a total of 36 bits of four symbols are transmitted and a complete cycle is concluded, so that transmission of a fifth symbol is carried out similarly as the transmission of the first symbol.

FIG. 2 illustrates the transmission of such a cycle, in which 36 bits are transmitted in the 36 intervals UI0-UI35. The input signals r0-r3 respectively have their own clock clk0-clk3, the clocks clk0-clk3 respectively being phase-shifted by 90° to one another.

A control device of the device 1 illustrated in FIG. 3 accordingly drives the multiplex device m0a via the control line s0a and the bit storage device i0a via the control line e0a, in such a way that the multiplex device m0a switches the input signal r0 through to the bit storage device i0a in the interval UI0 and the signal from the input line r0 is therefore stored in the bit storage device i0a with the rising edge of the clock signal clk0. In a next interval UI1 the control device drives the multiplex device m1a via the control line s1a and the bit storage device i1a via the control line e1a, in such a way that the input signal r1 is switched through to the bit storage device i1a and the input signal r1 is stored in the bit storage device i1a. Accordingly, the multiplex devices m2a-m8a are driven via the control lines s2a-s8a and the bit storage devices i2a-i8a are driven via the control lines e2a-e8a, in such a way that the 9 bits of the first symbol are stored in the bit storage devices i0a-i8a. This first symbol can now be output via the outputs Q of the bit storage devices i0a-i8a and postprocessed. This first symbol is stored via a clock signal frmclk of the postprocessing unit (not illustrated) in output bit storage devices f0-f8 via the multiplex device mab.

A second symbol, which is transmitted via the input signals r0-r3, is stored in a similar way in the bit storage devices i0b-i8b via the multiplex devices m0b-m8b. To this end, the control device drives the multiplex device m0b and the bit storage device i0b via the control lines s0b and e0b, in such a way that the input signal r1 is connected to the bit storage device i0b in an interval UI9 and bit 0 of the second symbol is therefore stored in the bit storage device i0b. In a comparable way, bits 1-8 of the second symbol are stored in the bit storage devices i1b-i8b in the intervals UI10-17. The second symbol is then available at the outputs of the bit storage devices i0b-i8b, and can then be stored in the output bit storage devices f0-f8 via the clock signal frmclk of the postprocessing unit via the multiplex device mab.

After this, bits 0-8 of a third symbol are stored in a similar way in the bit storage devices i0a-i8a via the multiplex devices m0a-m8a in the intervals UI18-UI26, and are subsequently stored for postprocessing in the output bit storage devices f0-f8 with the clock signal frmclk. After this, the fourth symbol is stored from the input signals r0-r3 in the bit storage devices i0b-i8b via the multiplex devices m0b-m8b in the intervals UI27-UI35, and is subsequently stored for postprocessing in the output bit storage devices f0-f8 with the clock signal frmclk. In this way, a complete cycle is concluded and transmission of a fifth symbol is carried out similarly as the transmission of the first symbol.

As a result of using the multiplexers m0a-m8a and m0b-m8b, only 18 bit storage devices i0a-i8a and i0b-i8b are employed in this embodiment. A further reduction in the number of bit storage devices to nine is possible if the multiplexers of each bit storage device make all the input signals r0-r3 available to the bit storage devices and are suitably driven. Then, however, transfer of the symbols from the bit storage devices into the output bit storage devices f0-f8 with the aid of the clock signal frmclk is time-critical, since this transfer must be carried out precisely between two transmitted data bits. In contrast, the device illustrated in FIG. 3 is very robust and non-critical in respect of the output data clock frmclk, since the transferring rising clock edge may occur in a wide range as illustrated, for example, by the range fclkx in FIG. 2.

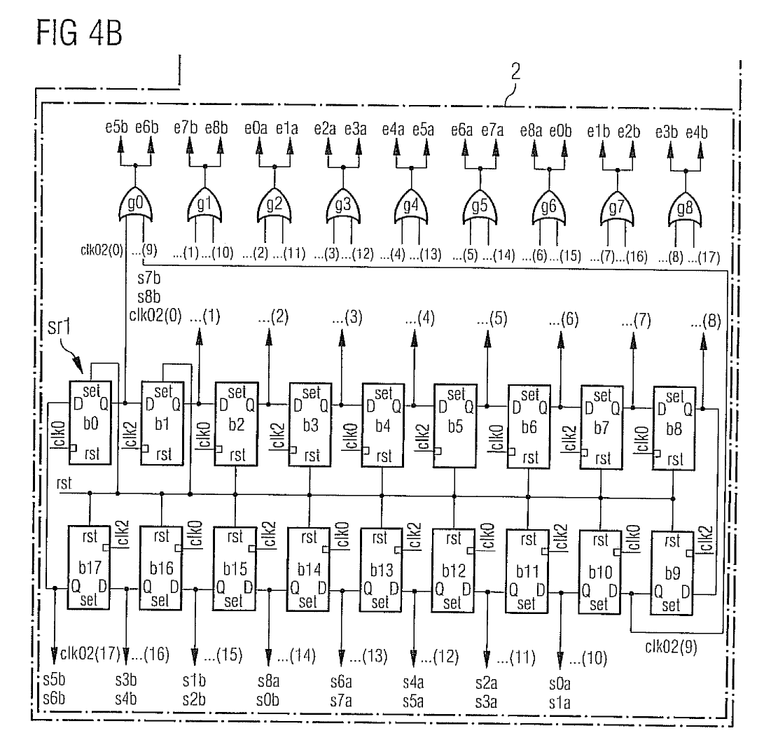

FIG. 4 illustrates an embodiment of the device 1 with a control device 2. The control device 2 comprises 18 shift register bit storage devices b0-b17 which are connected in a ring, in such a way that an output Q of the shift register bit storage device b0 is connected to an input D of the shift register bit storage device b1, an output Q of the shift register bit storage device b1 is connected to an input D of the shift register bit storage device b2, etc., and an output Q of the shift register bit storage device b17 is connected to an input D of the shift register bit storage device b0. The shift register bit storage devices are driven alternately with the clock signals clk0 and clk2, in such a way that shift register bit storage device b0 is driven by clock signal clk0, shift register bit storage device b1 is driven by clock signal clk2, shift register bit storage device b2 is driven by clock signal clk0, etc., and shift register bit storage device b17 is driven by clock signal clk2. The shift register bit storage devices b0 and b1 are preset with logical ones at an initialization time, whereas the shift register bit storage devices b2-b17 are initialized with logical zeros.

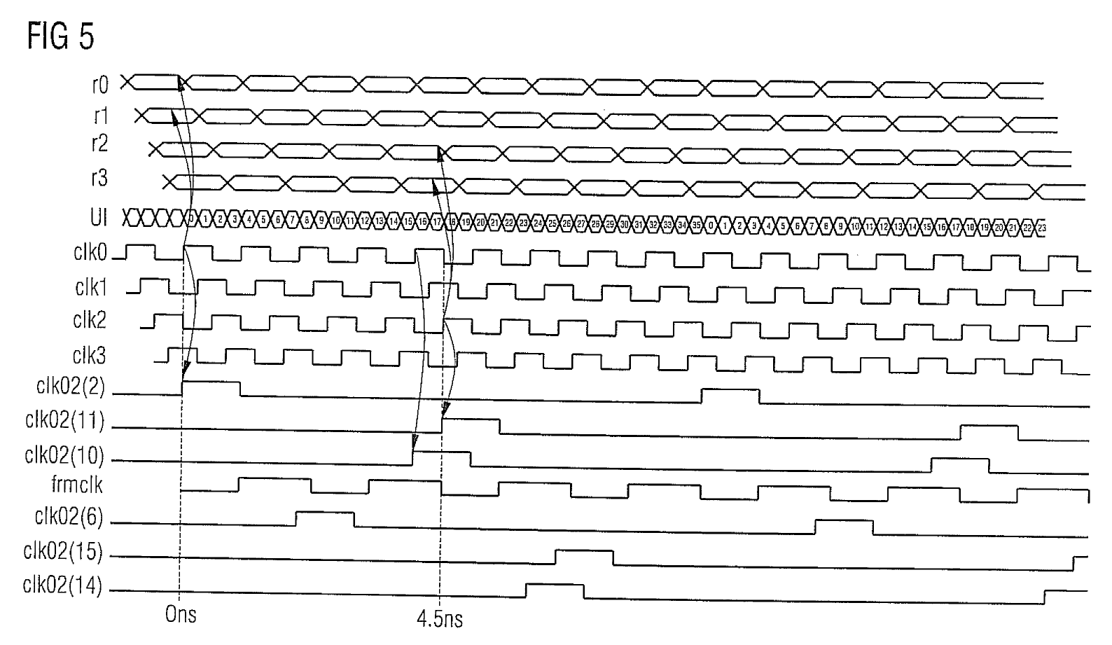

Since the clock signals clk0 and clk2 are phase-shifted by 180°, the two logical ones in the shift register arrangement sr1 are shifted forward by one position in the shift register arrangement sr1 with each rising edge of the clock signals clk0 and clk2. After 18 rising edges of the clock signals clk0 and clk2, the initial state is reached again and a cycle is concluded. In order to store the 36 bits, which are delivered via the four input signals r0-r3, in the bit storage devices i0a-i8a and i0b-i8b as described in connection with FIG. 3, two bit storage devices are respectively driven for each of the 18 states of the control device 2. FIG. 5 illustrates the way in which such driving is possible: at time 0 ns, the input signals r0 and r1 can be transferred into the bit storage devices with the rising edge of clk0, because both input signals are stably applied at this time. Likewise, storage of the input signals r2 and r3 with the rising edge of the clock signal clk2 is possible at time 4.5 ns, because these input signals are also stably applied at this time.

Such driving of the bit storage devices i0a-i8a and i0b-i8b is achieved by two bit storage devices, which store consecutive data of the input signals, being driven simultaneously. This pair of bit storage devices is driven via the OR gates g0-g8 of the control device 2. For example, gate g2 drives the bit storage devices i0a and i1a via the control lines e0a and e1a. OR gate g3 correspondingly drives the bit storage devices i2a and i3a via the control lines e2a and e3a. The further driving is selected comparably, and can be seen from FIG. 4.

Each of the OR gates g0-g8 has two inputs, which are connected to outputs Q of the shift register bit storage devices in such a way that each of the OR gates g0-g8 is driven precisely once during the first nine states of a cycle of the shift register arrangement sr1, and the OR gates g0-g8 are again driven precisely once during the second nine states of a cycle of the shift register arrangement sr1 and in the same sequence as by the first nine states of the shift register arrangement sr1. Each of the nine OR gates g0-g8 is therefore driven precisely twice in the course of a cycle of the shift register arrangement sr1, and each of the bit storage devices i0a-i8a and i0b-i8b is therefore driven precisely twice as described in connection with FIG. 3.

In addition, the control device 2 also drives the multiplex devices m0a-m8a and m0b-m8b. The driving is carried out via the signals s0a-s8a and s0b-s8b. As illustrated in FIG. 4, the signals of the control lines s0a-s8a and s0b-s8b are obtained directly from the outputs of the outputs Q of the shift register bit storage devices b0 and b10-b17. The effect achieved by this is that a first input signal is output via the associated multiplex device to the bit storage device when first driving a bit storage device, and a second input signal is output via the associated multiplex device to the bit storage device when driving the same bit storage device for the second time within the cycle.

For example, the bit storage device i0a is driven during a cycle of the shift register device of the control device 2, on the one hand when the first logical one of the circulating pair of logical ones is stored in the shift register bit storage device b2, a rising edge being output via the output Q of the shift register bit storage device b2 via the connection clk02 (2) to the OR gate g2 and being output from there via the control line e0a to the bit storage device i0a, while the multiplex device m0a is driven with a logical zero via the control line s0a from the output Q of the shift register bit storage device b10. At a later time in the cycle, the bit storage device i0a is driven a second time by the shift register bit storage device b11 as soon as the first logical one of the circulating pair of logical ones is stored in the shift register bit storage device b11. Then, a rising edge at the output of the shift register bit storage device b11 is output via a connection clk02 (11) to the OR gate g2, which outputs this rising edge via the control line e0a to the bit storage device i0a. At this time, the multiplex device m0a is driven with a logical one via the control line s0a from the output Q of the shift register bit storage device b10, and therefore switches the input signal r2 through to the bit storage device i0a.

Comparable driving is likewise provided by the control device 2 for the other bit storage devices i1a-i8a and i0b-i8b as well as the multiplex devices m1a-m8a and m0b-m8b. The control device 2 illustrated in FIG. 4 therefore achieves driving of the bit storage devices in such a way that the serial input signals r0-r3 are stored in the bit storage devices according to the manner described in FIG. 3.

The control device 2 of this embodiment employs only 18 shift register bit storage devices b0-b17 and nine OR gates g0-g8. Reliable driving of the bit storage devices is nevertheless ensured, because only few signals within the control device change their level at each change of state of the control device. This additionally reduces the power consumption. Since the shift register bit storage devices b0-b17 are driven with clocks phase-shifted by 180°, it is furthermore possible to design these shift register bit storage devices both as edge-triggered flip-flops and as level-controlled transparent latches. As transparent latches are generally less complex in terms of circuit technology than edge-triggered flip-flops, this embodiment employs particularly little chip area for implementation on a semiconductor chip.

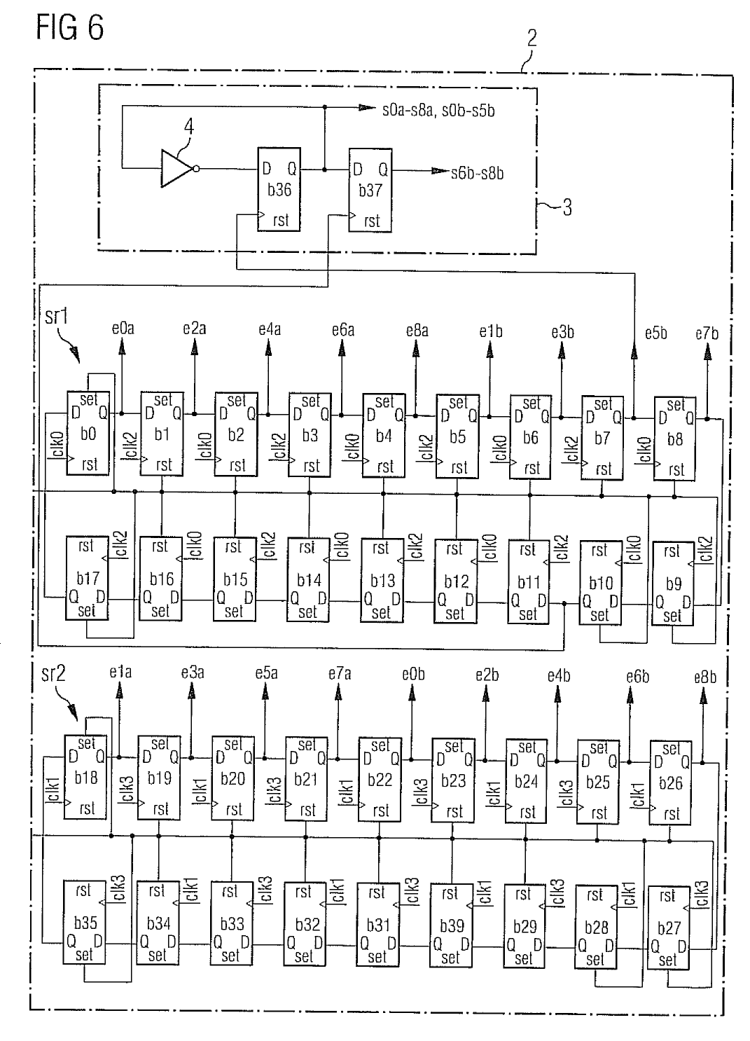

FIG. 6 illustrates an embodiment of a control device 2 of a device 1. In order to preserve clarity of the figure, that part of the device 1 which is illustrated in FIG. 3 has not been represented again here. Reference will, however, be made to signals and components of FIG. 3.

The control device 2 comprises two looped shift register arrangements sr1, sr2, which respectively comprise 18 shift register bit storage devices b0-b17 and b18-b35. The shift register bit storage devices b0-b17 of the first shift register arrangement sr1 are driven alternately by clock signals clk0 and clk2, shift register bit storage device b0 being driven by clk0, shift register bit storage device b1 being driven by clk2, etc. The shift register bit storage devices b18-b35 of the second shift register arrangement sr2 are driven by clock signals clk1 and clk3. At an initialization time, a logical one is respectively stored in the shift register bit storage devices b0, b9, b10, b17 and b18, b27, b28, b35 via an initialization line rst, whereas a logical zero is respectively stored in the bit storage devices b1-b8, b11-b16 and b19-b26, b29-b34. The shift register bit storage devices b0-b35 are configured in such a way that data, which are applied to their inputs D, are stored by them and provided at their outputs Q in the event of a rising edge of the respective driving clock signal. An effect achieved by this is that two pairs of logical ones respectively circulate in each shift register arrangement sr1, sr2, the initial state of the shift register arrangements sr1, sr2 respectively being reached again after nine clocks of the clock signals clk0-clk3 so that a cycle of the control device 2 is concluded.

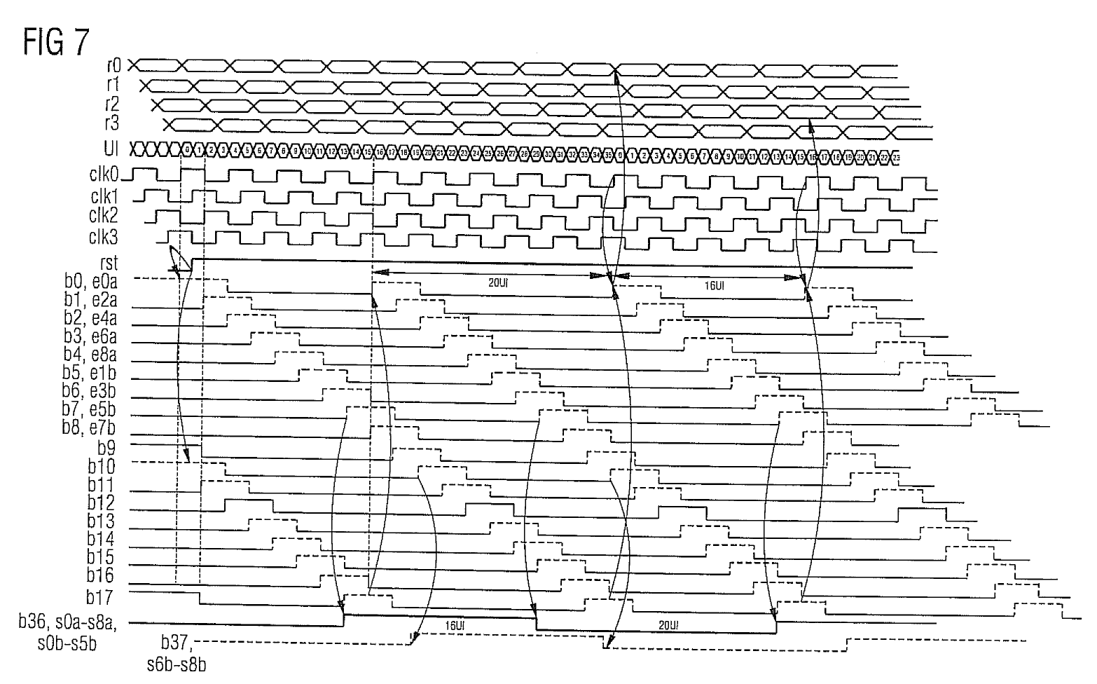

Within each cycle of the control device 2, each shift register arrangement sr1, sr2 has 18 different states. Since the bit pattern circulating in the shift register arrangement sr1, sr2 comprises two separate pairs of logical one levels, these 18 states can be used directly in order to drive one of the bit storage devices, the bit storage devices i0a, i2a, i4a, i6a, i8a, i1b, i3b, i5b, and i7b being driven by the outputs of the shift register bit storage devices b0-b8 and the bit storage devices i1a, i3a, i5a, i7a, i0b, i2b, i4b, i6b, and i8b being driven by the shift register bit storage devices b18-b26. Each of the bit storage devices i0a-i8a and i0b-i8b is therefore respectively driven twice in the course of a cycle of the control device 2. FIG. 7 illustrates an example time control profile of the control outputs e0a, e2a, e4a, e6a, e8a, e1b, e3b, e5b, and e7b, which correspond to the outputs of the outputs Q of the shift register bit storage devices b0-b8, as well as the outputs of the outputs Q of the shift register bit storage devices b9-b17. The bit storage devices are therefore driven according to the description of FIG. 3 in order to store four symbols via the serial input signals r0-r3 in the bit storage devices within a cycle of the control device 2.

In order to drive the multiplex devices m0a-m8a and m0b-m8b, the control device 2 has a switching device 3. The switching device 3 comprises two switching bit storage devices b36 and b37, the input D of the switching bit storage device b36 being connected via an inverter 4 to the output Q of the switching bit storage device b36 and the input D of the switching bit storage device b37 being connected to the output Q of the switching bit storage device b36. The control input of the switching bit storage device b36 is connected to the control signal e5b. The control input of the switching bit storage device b37 is connected to the output Q of the shift register bit storage devices b10. The output of the switching bit storage device b36 is additionally connected to all the control inputs of the multiplex devices m0a-m8a and m0b-m5b via the control lines s0a-s8a and s0b-s5b. The output of the switching bit storage device b37 is connected to the control inputs of the multiplex devices m6b-m8b via the control lines s6b-s8b.

The switching device 3 now operates in the following way. After initialization of the control device, the switching bit storage devices b36 and b37 respectively have a logical zero level at their outputs. Accordingly, the multiplex devices m0a-m8a and m0b-m8b respectively switch the upper input in FIG. 3 through to the associated bit storage device. The bit storage devices i0a-i8a and i0b-i4b are then driven by the shift register bit storage devices b0-b6 and b18-b24 via the control lines e0a-e8a and e0b-e4b, so that the nine bits of a first symbol are stored in the bit storage devices i0a-i8a and the first five bits of a second symbol are stored in the bit storage devices i0b-i4b. Next, shift register bit storage device b7 drives the bit storage device i5b via the control line e5b and stores the sixth bit of the second symbol there. Simultaneously, the control line e5b drives the switching bit storage device b36 whose input D is fed back via the inverter 4 to the output Q. The driving of the multiplex devices m0a-m8a and m0b-m5b connected to the output Q of the switching bit storage device b36 therefore also changes at this time. The multiplexers m0a-m8a and m0b-m5b therefore now respectively switch their lower input in FIG. 3 through to the corresponding bit storage device. Next, the bit storage devices i6b, i7b and i8b are respectively driven in succession by the shift register bit storage devices b25, b8 and b26 via the control lines e6b, e7b and e8b, so that the seventh, eighth, and ninth bits of the second symbol are respectively stored there. Note that the multiplex devices m6b-m8b still switch their upper input illustrated in FIG. 3 through to the bit storage devices i6b-i8b at this time.

Next, the bit storage device i0a-i8a and i0b-i4b are driven via the outputs Q of the shift register bit storage devices b0-b6 and b18-b24 via the control lines e0a-e8a and e0b-e4b, and nine bits of a third symbol and the first five bits of a fourth symbol are stored, the multiplex devices m0a-m8a and m0b-m5b respectively switching their lower input illustrated in FIG. 3 through to the corresponding shift register bit storage devices. In addition, the switching bit storage device b37 is driven via the output at the output Q of the shift register bit storage device b10 and then stores the output signal of the switching bit storage device b36 (e.g., a logical one) and delivers it via the control lines s6b-s8b to the multiplex devices m6b-m8b. Now, therefore, all the multiplex devices m0a-m8a and m0b-m8b are driven in such a way that they switch the lower input illustrated in FIG. 3 through to the associated bit storage devices.

Next, the bit storage device i5b is driven by the shift register bit storage device b7 and stores the sixth bit of the fourth symbol, which is transmitted via the input line r0. In addition, the switching bit storage device b36 is driven via the control line e5b and thereupon stores the logical value zero. The multiplex devices m0a-m8a and m0b-m5b are therefore now driven via the control line s0a-s8a and s0b-s5b in such a way that the multiplex devices respectively switch the upper input illustrated in FIG. 3 through to the corresponding bit storage devices. Subsequently, the bit storage devices i6b, i7b, and i8b are respectively driven in succession via the signal lines e6b, e7b, and e8b by the shift register bit storage devices b25, b8, and b26 and the seventh, eighth, and ninth bit of the fourth symbol are respectively stored in the bit storage devices i6b, i7b, and i8b, at which time the multiplex devices m6b, m7b, and m8b switch their lower input illustrated in FIG. 3 through to the corresponding bit storage devices.

A complete cycle of the control device 2 is thereby executed, in which four symbols with nine bits each have been stored. At the start of the next cycle, the multiplex devices m6b-m8b are driven via the output Q of the shift register bit storage device b10 in such a way that, like the other multiplex devices m0a-m8a and m0b-m5b, they also switch their upper input illustrated in FIG. 3 through to the corresponding bit storage devices and are therefore set suitably in order to store the sixth symbol.

In conjunction with the control device 2, the switching device 3 illustrated in FIG. 6 enables reliable driving of the multiplex devices m0a-m8a and m0b-m8b of the device 1. The switching device 3 employs only few gate functions and therefore only a little chip area and has a low power consumption. Since they are driven alternately with clocks shifted by 180°, the shift register bit storage devices may be configured as edge-triggered flip-flops or as level-controlled transparent latches. As transparent latches are generally less complex in terms of circuit technology than edge-triggered flip-flops, this embodiment employs particularly little chip area for implementation on a semiconductor chip.

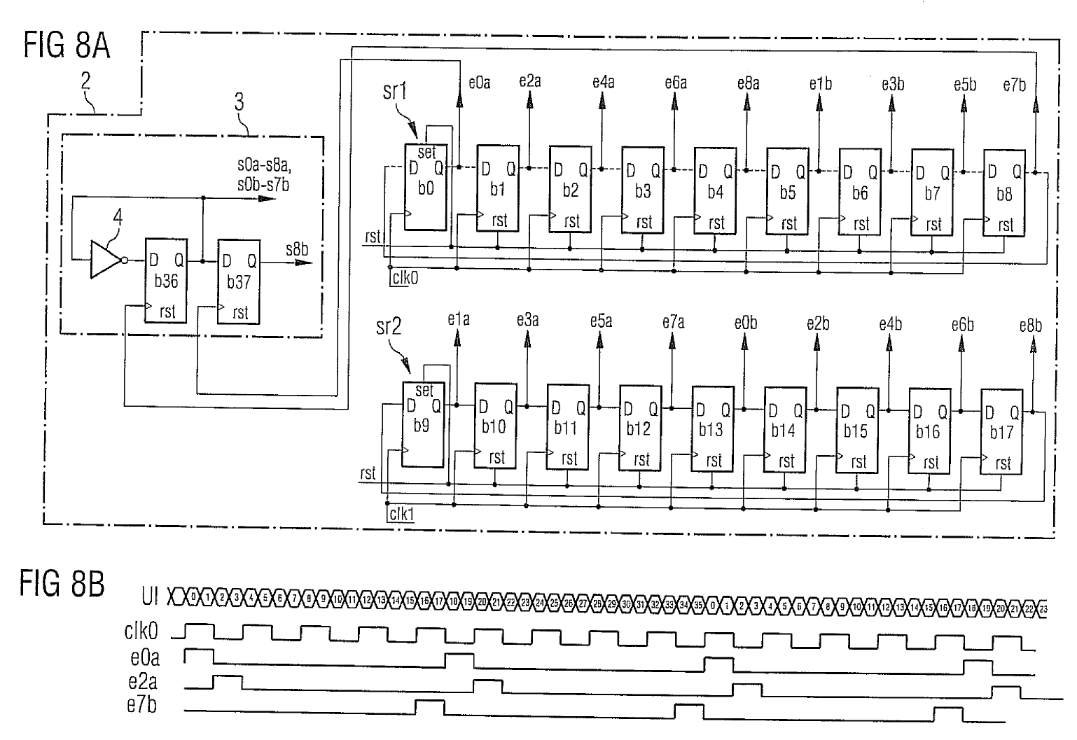

FIG. 8A illustrates an embodiment of a control device 2 of a device 1. In order to preserve clarity of the figure, that part of the device 1 which is illustrated in FIG. 3 has not been represented again here. Reference will, however, be made to signals and components of FIG. 3.

The control device 2 comprises two looped shift register arrangements sr1, sr2, which respectively comprise nine shift register bit storage devices b0-b8 and b9-b17. The first shift register arrangement sr1, which comprises the shift register bit storage devices b0-b8, is driven by a clock signal clk0. The second shift register arrangement sr2, which comprises the shift register bit storage devices b9-b17, is driven by a clock signal clk1. At an initialization time, a logical one is respectively stored in the shift register bit storage devices b0 and b9 via the initialization line rst, whereas a logical zero is respectively stored in the bit storage devices b1-b8 and b10-b17.

The shift register bit storage devices b0-b17 are configured in such a way that data, which are applied to their inputs D, are stored by them and provided at their outputs Q both in the event of a rising edge and in the event of a falling edge of the clock signal clk0 or clk1, respectively. The effect achieved by this is that the logical one which is shifted cyclically through the shift register arrangement sr1, sr2, already reaches its original position again after 4½ clock cycles of the clock signal clk0 or clk1, respectively, and a full cycle of the shift register arrangements sr1, sr2 is therefore already completed after 4½ clock cycles of the clock signals clk0 and clk1, respectively.

Within each cycle of the shift register arrangement sr1, sr2, the shift register arrangement sr1, sr2 has nine different states. These nine states can respectively be used directly in order to drive one of the bit storage devices, the bit storage devices i0a, i2a, i4a, i6a, i8a, i1b, i3b, i5b, and i7b being driven by the outputs of the shift register bit storage devices b0-b8 and the bit storage devices i1a, i3a, i5a, i7a, i0b, i2b, i4b, i6b, and i8b being driven by the shift register bit storage devices b9-b17. It is not necessary to use the clock signals clk2 and clk3, because clk2 corresponds to clk0 phase-shifted by 180° and clk3 corresponds to clk1 phase-shifted by 180°, and the shift register bit storage devices react both to the rising edges and to the falling edges of the driving clock signals.

FIG. 8B illustrates an example time control profile of the control outputs e0a, e2a and e7b of the first shift register arrangement sr1. The bit storage device is driven as described above in connection with FIG. 3.

In order to drive the multiplex devices m0a-m8a and m0b-m8b, the control device 2 has a switching device 3. The switching device 3 comprises two switching bit storage devices b36 and b37, the input D of the switching bit storage device b36 being connected via an inverter 4 to the output Q of the switching bit storage device b36 and the input D of the switching bit storage device b37 being connected to the output Q of the switching bit storage device b36. The control input of the switching bit storage device b36 is connected to the control signal e7b of the control device 2. The control input of the switching bit storage device b37 is connected to the control signal e0a of the control device 2. The output Q of the switching bit storage device b36 is additionally connected to all the control inputs of the multiplex devices m0a-m8a and m0b-m7b via the control lines s0a-s8a and s0b-s7b. The output of the switching bit storage device b37 is connected to the multiplex device m8b via the control line s8b.

The switching device 3 now operates in the following way. After initialization of the control device, the switching bit storage devices b36 and b37 respectively have a logical zero level at their outputs. Accordingly, the multiplex devices m0a-m8a and m0b-m8b respectively switch the upper input in FIG. 3 through to the associated bit storage device. The bit storage devices i0a-i8a and i0b-i6b are then driven by the shift register bit storage devices b0-b7 and b9-b16 via the control lines e0a-e8a and e0b-e6b, so that the nine bits of a first symbol are stored in the bit storage devices i0a-i8a and the first seven bits of a second symbol are stored in the bit storage devices i0b-i6b. Next, shift register bit storage device b8 drives the bit storage device i7b via the control line e7b and stores the eighth bit of the second symbol there. Simultaneously, the control line e7b drives the switching bit storage device b36 whose input D is fed back via the inverter 4 to the output Q. The driving of the multiplex devices m0a-m8a and m0b-m7b connected to the output Q of the switching bit storage device b36 therefore also changes at this time. The multiplexers m0a-m8a and m0b-m7b therefore now respectively switch their lower input in FIG. 3 through to the corresponding bit storage device. Next, the bit storage device i8b is driven by the shift register bit storage device b17 via the control line e8b, so that the ninth bit of the second symbol is stored there. Note that the multiplex device m8b still switches its upper input r1 through to the bit storage device i8b at this time. Next, the bit storage device i0a is driven via the output of the shift register bit storage device b0 via the control line e0a and the first bit of a third symbol, which is output to the bit storage device i0a via r2, is stored. In addition, the switching bit storage device b37 is driven via the control line e0a and thereupon stores the output signal Q of the switching bit storage device b36 (e.g., a logical one) and outputs it via the control line s8b to the multiplex device m8b. Now, therefore, all the multiplex devices m0a-m8a and m0b-m8b are driven in such a way that they switch the lower input illustrated in FIG. 3 through to the associated bit storage devices.

Subsequently, the bit storage devices i0a-i8a and i0b-i6b are driven by the shift register bit storage devices b1-b7 and b9-b16, and therefore bits 1-8 of the third symbol are stored in the bit storage devices i1a-i8a and bits 0-6 of a fourth symbol are stored in the bit storage devices i0b-i6b. Next, the bit storage device i7b is driven by the shift register bit storage device b8 and stores bit to 7 of the fourth symbol, which is transmitted via the input line r2. In addition, the switching bit storage device b36 is driven via the control line e7b and thereupon stores the logical value zero. The multiplex devices m0a-m8a and m0b-m7b are therefore now driven via the control line s0a-s8a and s0b-s7b in such a way that the multiplex devices respectively switch the upper input illustrated in FIG. 3 through to the corresponding bit storage devices. Subsequently, bit storage device i8b is driven via the signal line e8b by the shift register bit storage device b17 and bit 8 of the fourth symbol, which is transmitted via the input line r3, is stored in the bit storage device i8b. Next, via the control line e0a, shift register bit storage device b0 drives the bit storage device i0a which stores bit 0 of a fifth symbol. In addition, the switching bit storage device b37 is driven by the control line e0a in such a way that the switching bit storage device b37 stores the logical value zero and, via the control line s8b, drives the multiplexer m8b in such a way that the multiplexer m8b connects the input liner 1 to the bit storage device i8b. A complete cycle of the control device 2 is thereby executed, in which four symbols with nine bits each are transmitted.

In conjunction with the control device 2, the switching device 3 illustrated in FIG. 8A permits reliable driving of the multiplex devices of the device 1. The switching device 3 employs only few gate functions and therefore only a little chip area and has a low power consumption.

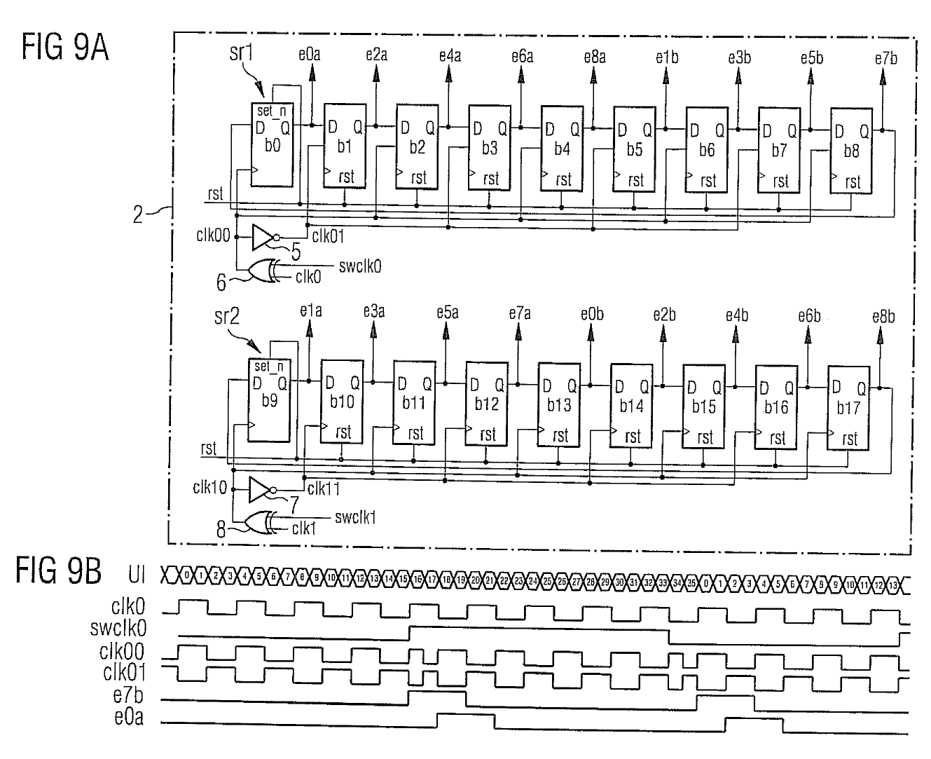

FIG. 9A illustrates an embodiment of the control device 2. In order to preserve clarity of the figure, that part of the device 1 which is illustrated in FIG. 3 has not been represented again here. Reference will, however, be made to signals and components of FIG. 3.

Like the control device illustrated in FIG. 8A, the control device 2 illustrated in FIG. 9A comprises two looped shift register arrangements sr1, sr2, wherein a first shift register arrangement sr1 comprises nine shift register bit storage devices b0-b8, an inverter 5, and an XOR gate 6. The shift register bit storage devices b0-b8 are connected to form a ring, an output Q of the shift register bit storage device b0 being connected to an input D of the shift register bit storage device b1, an output Q of the shift register bit storage device b1 being connected to an input D of the shift register bit storage device b2, etc., and finally an output Q of the shift register bit storage device b8 being connected to an input D of the shift register bit storage device b0. The shift register bit storage devices b1, b3, b5 and b7 are driven by a clock signal clk01, which is phase-shifted by 180° relative to the driving clock signal clk00 of the shift register bit storage devices b0, b2, b4, b6, and b8. This is achieved via the inverter 5, as illustrated in the circuit diagram in FIG. 9A. In addition, the shift register arrangement sr1 comprises an XOR gate 6, which is used in order to be able to selectively invert the delivered clock clk0 with the aid of the control line swclk0.

With the aid of a reset input rst, the shift register bit storage devices are set at an initialization time in such a way that shift register bit storage device b0 is set to a logical one value and the other shift register bit storage devices b1-b8 are respectively set to a logical zero value. The shift register bit storage devices b0-b8 are configured in such a way that they accept the value applied to their input with a rising edge of their drive input.

The second shift register arrangement sr2 of the control device 2 comprises the shift register bit storage devices b9-b17, an inverter 7, and an XOR gate 8. The structure and functionality of the second shift register arrangement sr2 are identical to the first shift register arrangement sr1, except that the second shift register arrangement sr2 is driven by a clock clk1 which can selectively be inverted with the aid of the control signal swclk1 which is delivered to the XOR gate 8, and from which the clock signals clk10 and clk11 for driving the shift register bit storage devices b9-b17 are generated.

Since the bit storage devices b0-b8 and b9-b17 are respectively driven alternately by clock signals with a 180° phase shift, the state of the shift register arrangements sr1 and sr2 changes with each edge of the driving clock signal clk0 or clk1 except when the circulating logical one signal is transferred from the shift register bit storage device b8 and b17 to the shift register bit storage device b0 and b1, respectively, because the shift register bit storage devices b8 and b0 and respectively b17 and b9 are driven by clock signals with the same phase. So that the circulating logical one signal is moved forward by one position inside the shift register arrangement sr1 or sr2 with each edge change of the driving clock signal clk0 or clk1, respectively, the control inputs swclk0 and swclk1 respectively change their values whenever the circulating logical one signal is stored in the shift register bit storage device b8 or b17. The clock signal clk0 or clk1 supplied in the first or second shift register arrangement sr1 or sr2 is therefore inverted and the circulating logical one signal can be transferred into the shift register bit storage devices b0 and b9 with the next edge of the signal clk0 or clk1.

FIG. 9B illustrates an example time control profile of the first shift register arrangement sr1. Therefore, similarly as for the shift register arrangements sr1, sr2 of FIG. 8A, a complete circuit of the logical one is achieved within 4½ clock cycles of the clock control signal clk0 or clk1. At the control signal outputs e0a-e8a and e0b-e8b, identical control signals are therefore generated as in the control device 2 of FIG. 8A. The functionality is accordingly similarly to the functionality described in connection with FIG. 8A.

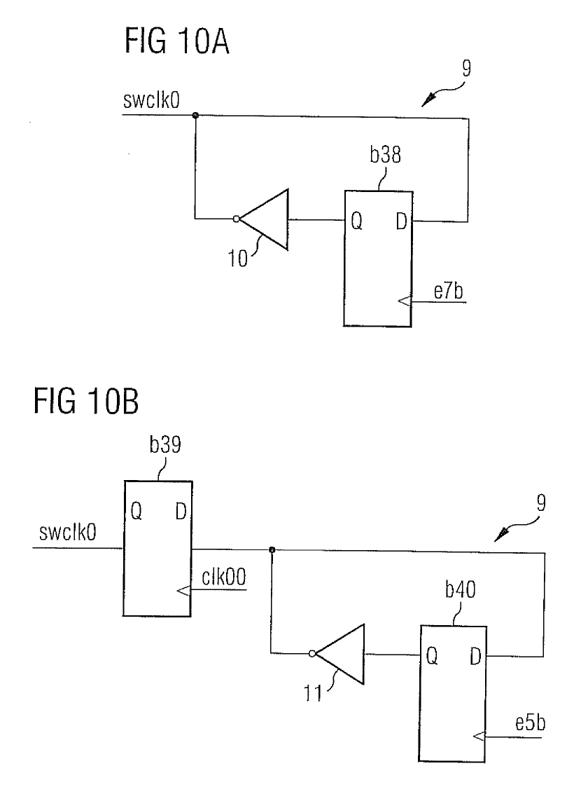

FIGS. 10A and 10B illustrate two different embodiments of a clock switching device 9, which can be used for switching the clock clk0 in conjunction with the control device 2 as illustrated in FIG. 9. The clock switching device 9 of FIG. 10A comprises a switching bit storage device b38, an input D of which is connected via an inverter 10 to its output Q. The control input of the switching bit storage device b38 is driven by the control signal e7b of the shift register bit storage device b8 of FIG. 9A. The level at the output of the inverter 10 therefore changes each time the switching bit storage device b38 is driven (i.e., with each cycle of the logical one level in the shift register arrangement sr1 of the control device 2). The output signal of the inverter 10 is sent via the control line swclk0 to the XOR gate 6 of the shift register arrangement sr1 of FIG. 9A. The clock for driving the shift register bit storage devices b0-b8 is therefore switched each time the logical one level, which is shifted through in the shift register arrangement sr1, passes from shift register bit storage device b8 to shift register bit storage device b0 so that the example time control profile illustrated in FIG. 9B is achieved.

FIG. 10B illustrates an embodiment of such a clock switching device 9, which comprises two bit storage devices b39 and b40 and an inverter 11. The output Q of the switching bit storage device b40 is fed back via the inverter 11 to the input D of the switching bit storage device b40. In addition, the output of the inverter 11 is connected to the input D of the switching bit storage device b39, which is driven via the drive clock clk00. The switching bit storage device b40 is driven via the output of the shift register bit storage device b7 via the control line e5b. Via the connection line swclk0, the output of the switching bit storage device b39 drives the shift register arrangement sr1 of the control device 2 of FIG. 9A. Each time when the circulating logical one level in the shift register arrangement sr1 is stored in the shift register bit storage device b7, the switching bit storage device b40 is driven via the control line e5b and the output level at the output of the inverter 11 is therefore inverted. With the next rising edge of the clock signal clk00, on the one hand the shift register bit storage device b8 is driven and therefore the circulating logical one level of the shift register arrangement sr1 is shifted forward by one position, and in addition via the switching bit storage device b39 the value of the output of the inverter 11 is stored in the switching bit storage device b39 and delivered via the control line swclk0 to the shift register arrangement sr1 of FIG. 9. Therefore, with the aid of the XOR gate 6, the drive clocks clk00 and clk01 are inverted and the desired example drive profile illustrated in FIG. 9B is therefore achieved.

Although the switching device 9 of FIG. 10B employs somewhat more chip area since two bit storage devices are used, it is nevertheless advantageous for time-critical applications, because the level of the control signal swclk0 already changes simultaneously with the change of the level at the output of the shift register bit storage device b8.

A clock switching device for generating the drive signal for the shift register bit storage devices b9-b17 of the shift register arrangement sr2 can be produced in a comparable way and will not therefore be described in detail here.

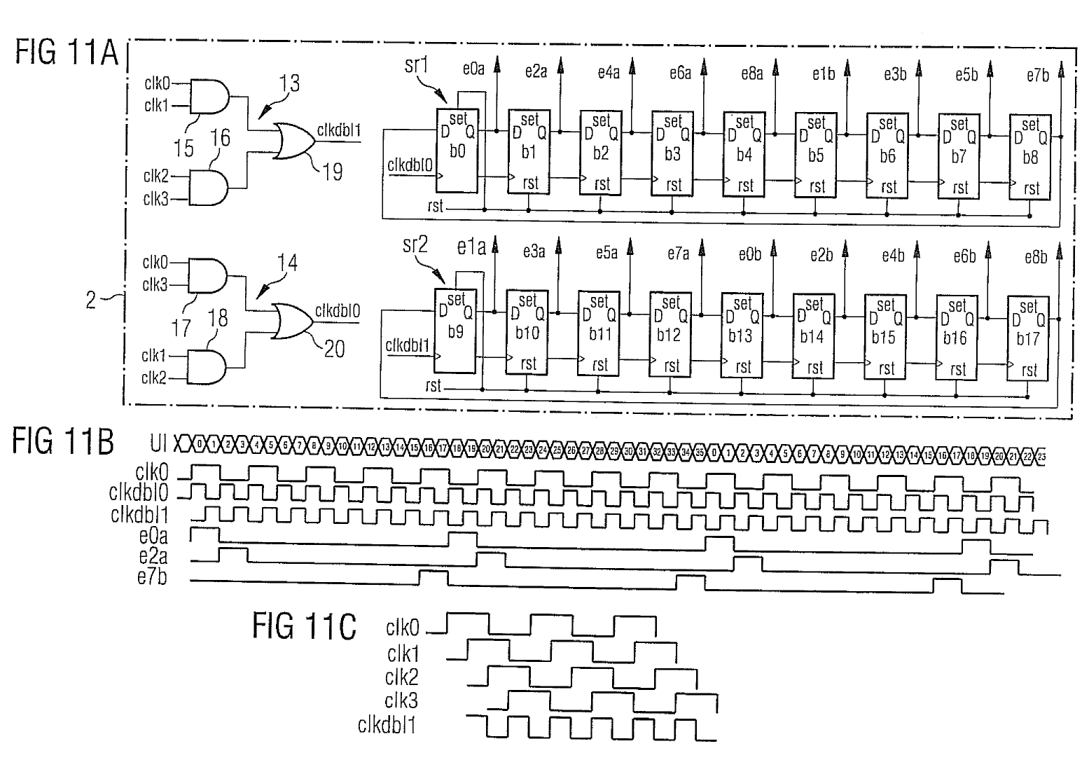

FIG. 11A illustrates an embodiment of a device 1 comprising a control device 2. In order to preserve clarity of the figure, that part of the device 1 which is illustrated in FIG. 3 has not been represented again here. Reference will, however, be made to signals and components of FIG. 3.

The control device 2 comprises two shift register arrangements sr1, sr2, a first shift register arrangement sr1 comprising the shift register bit storage devices b0-b8, and a second shift register arrangement sr2 comprising the shift register bit storage devices b9-b17. The shift register bit storage devices of each shift register arrangement sr1, sr2 are looped (i.e., the output Q of shift register bit storage device b8 is connected to the input D of the shift register bit storage device b0 and the output Q of shift register bit storage device b17 is connected to the input D of the shift register bit storage device b9). At an initialization time, via an initialization connection rst, a logical one level is stored in the shift register bit storage devices b0 and b9 whereas a logical zero level is stored in the other shift register bit storage devices. The first shift register arrangement sr1 is driven by a control clock clkdb10 in such a way that, with each rising edge of the clock signal clkdb10, the logical one level is shifted forward by one position in the shift register arrangement sr1 or, at the end, is fed back from shift register bit storage device b8 into the shift register storage device b0. The second shift register arrangement sr2 is driven in a similar way by the clock signal clkdb11.

In a similar way as described in connection with FIG. 8A, the outputs of the shift register bit storage devices b0-b17 drive the bit storage devices i0a-i8a and i0b-i8b via the control lines e0a-e8a and e0b-e8b as well as the multiplex devices m0a-m8b and m0b-m8b. The functionality of the shift register arrangements sr1, sr2 of the control device 2 is comparable to the shift register arrangements sr1, sr2 illustrated in FIG. 8A, the shift register bit storage devices b0-b17 of FIG. 11 reacting to rising edges of the drive signal.

Consequently, control signals which are different from those in FIG. 8A, and which have twice the clock frequency, are employed.

Such clock control signals may, for example, be obtained using the clock doubling devices 13 and 14 illustrated in FIG. 11A. By the clocks of the input signals clk0 and clk1 and respectively clk2 and clk3 being combined via AND gates 15 and 16 and the output signals of the AND gates 15 and 16 being combined with the aid of the OR gate 19, a control signal clkdb11 is generated whose clock frequency corresponds to twice the clock frequency of the input signal clk1, and which always has a rising edge whenever clk1 or clk3 has a rising edge.

An example time control profile of clk0-clk3 and clkdb11 is illustrated in FIG. 11C. The drive signal clkdb11 obtained can now be used in order to drive the shift register bit storage devices b9-b17.

In a comparable way, a clock doubling device 14 can be produced from the clocks of the input signals clk0-clk3, the AND gates 17 and 18 and the OR gate 20 as represented in FIG. 11A. The drive clock clkdb10 obtained is used for driving the shift register bit storage devices b0-b8.

FIG. 11B illustrates an example overall time control profile of the control device of FIG. 11A. The bit storage device is driven in a similar way as described above in connection with the description of FIG. 8A.

Since the employed chip area of a shift register bit storage device which reacts only to rising edges is less than the employed chip area of a shift register bit storage device which reacts to both rising and falling edges, such as the one used in FIG. 8A, the control device 2 of FIG. 11A employs less chip area than the control device 2 of FIG. 8A.

While exemplary embodiments have been described above, various modifications may be implemented in other embodiments. For example the number of input signals and/or the number of bits of the symbols to be de-serialized may be adapted to the needs of the specific application. Furthermore, the devices and methods of embodiments may be used, for example, for the parallelization of serial digital signals transmitted between computing devices and storage and I/O devices, or transmitted between data transmission devices in a data transmission network.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A device configured to parallelize N serial digital input signals, the device comprising:
a plurality of bit storage devices configured to each respectively store one bit of the N serial digital input signals and provide the one stored bit as a bit of a parallel digital output signal with a bit width M, wherein M is greater than N, N is greater than 1, and the number of bit storage devices is at least M;
wherein symbols with a bit width M are transmitted via the N serial digital input signals such that each of the N serial digital input signals transmits a fraction of the respective symbol; and
a control device configured to drive the plurality of bit storage devices cyclically such that at least M bits of the serial digital input signals, which belong to one symbol, are stored in the bit storage devices within a cycle.

2. The device according to claim 1, wherein each of the bit storage devices is allocated to precisely one bit position of the symbol, and wherein the device comprises:
a plurality of multiplex devices each including an input side configured to receive a plurality of the N serial digital input signals and an output side coupled to an input of at least one of the bit storage devices and together are configured to supply the serial digital input signals, which transmit data bits for the bit position of the respective bit storage device, selectively to the respective bit storage devices; and
wherein the control device is configured to drive the plurality of multiplex devices.

3. The device according to claim 2, wherein the control device comprises:
a switching device configured to drive the multiplex devices, wherein at a time when a special bit storage device stores a data bit, the switching device drives all the multiplex devices which are not allocated to the special bit storage device and at another time when the special bit storage device does not store a data bit, the switching device drives the multiplex device which is allocated to the special bit storage device.

4. The device according to claim 1, wherein the control device comprises:
at least one looped shift register arrangement including a plurality of shift register bit storage devices connected in a ring.

5. The device according to claim 4, wherein N is an even number, the control device comprises N/2 looped shift register arrangements, the N serial digital input signals have the same clock frequency and a different clock phase angle, the clock phase angles respectively are shifted approximately by 360°/N, the number of shift register bit storage devices of each of the N/2 looped shift register arrangements is even, the shift register bit storage devices of one of the N/2 looped shift register arrangements are driven alternately with clocks phase-shifted by 180°, and the shift register bit storage devices of the k^{th} of the N/2 looped shift register arrangements are driven with clocks having a phase angle of (k−1)*360°/N and 180°+(k−1)*360°/N, with k=1, 2, . . . N/2.

6. The device according to claim 4, wherein N is an even number, the control device comprises one looped shift register arrangement, the N serial digital input signals have the same clock frequency and a different clock phase angle, the clock phase angles respectively are shifted approximately by 360°/N, the number of shift register bit storage devices of the looped shift register arrangement are even, and the shift register bit storage devices of the looped shift register arrangement are driven alternately with clocks phase-shifted by 180°.

7. The device according to claim 4, wherein N is an even number, the control device comprises N/2 looped shift register arrangements, the N serial digital input signals have the same clock frequency and a different clock phase angle, the clock phase angles respectively are shifted approximately by 360°/N, the shift register bit storage devices of the N/2 looped shift register arrangements store a value applied to their inputs both in the event of a rising edge of a drive signal and in the event of a falling edge of a drive signal, and the shift register bit storage devices of the k^{th} of the N/2 looped shift register arrangements are driven with clocks having a phase angle of (k−1)*360°/N or 180°+(k−1)*360°/N, with k=1, 2, . . . N/2.

8. The device according to claim 4, wherein N is an even number, the control device comprises N/2 looped shift register arrangements, the N serial digital input signals have the same clock frequency and a different clock phase angle, the clock phase angles respectively are shifted approximately by 360°/N, and the shift register bit storage devices of the k^{th} of the N/2 looped shift register arrangements are driven with a clock which is derived via a clock doubling device from one of the clocks of the input signals having a phase angle of (k−1)*360°/N or 180°+(k−1)*360°/N and a doubled frequency compared with the frequency of the clock of the input signals, with k=1, 2, . . . N/2.

9. The device according to claim 4, wherein a bit pattern, which comprises a plurality of bit segments, is shifted through continuously in the looped shift register arrangement, the bit segments alternately having a first logical value and a second logical value different from the first logical value.

10. The device according to claim 4, wherein N is an even number, the control device comprises N/2 looped shift register arrangements, a bit pattern which comprises two bit segments is shifted through continuously in the looped shift register arrangement, a first of the two bit segments has a first logical value and a second of the two bit segments has a second logical value different from the first logical value, the N serial digital input signals have the same clock frequency and a different clock phase angle, the clock phase angles respectively are shifted approximately by 360°/N, the number L of shift register bit storage devices of each of the N/2 looped shift register arrangements are odd;
the shift register bit storage devices are driven alternately with a first and a second clock signal such that a first of the shift register bit storage devices and an L^{th} of the shift register bit storage devices are respectively driven with a first clock signal, the first clock signal is phase-shifted by 180° relative to the second clock signal, the shift register bit storage devices of the k^{th} of the N/2 looped shift register arrangements are driven with clocks having phase angle of (k−1)*360°/N or 180°+(k−1)*360°/N, with k=1, 2, . . . N/2; and
the clock signal for driving the shift register bit storage devices is phase-shifted by 180° by a clock switching device when the first bit of the first bit segment is transferred from the L^{th} shift register bit storage device to the first shift register bit storage device.

11. The device according to claim 1, wherein N is equal to 4.

12. The device according to claim 1, wherein M is equal to 9.

13. The device according to claim 1 wherein the number of storage devices is 18.

14. The device according to claim 1, wherein each of the bit storage devices is allocated to precisely one bit position of the symbol, and wherein the device comprises:
18 multiplex devices each including an input side configured to receive a plurality of the N serial digital input signals and an output side coupled to an input of at least one of the bit storage devices and together are configured to supply the serial digital input signals, which transmit data bits for the bit position of the respective bit storage device, selectively to the respective bit storage devices; and
wherein the control device is configured to drive the plurality of multiplex devices.

15. The device according to claim 1, wherein the device is formed on a semiconductor chip.

16. The device according to claim 1, wherein the device is formed on a DRAM semiconductor chip which comprises a serial interface for transmitting data and instructions in the form of data packets according to a predetermined protocol, wherein the device is configured to parallelize N serial digital input signals of the serial interface.

17. The device according to claim 1, wherein the device is formed on semiconductor chip of a central processing unit or a memory management processing unit which comprises a serial interface for transmitting data and instructions in the form of data packets according to a predetermined protocol, wherein the device is configured to parallelize N serial digital input signals of the serial interface.

18. A device for parallelizing N serial digital input signals, the device comprising:
at least M means for respectively storing one bit of the N serial digital input signals and providing the one stored bit as a bit of a parallel digital output signal with a bit width M, wherein M is greater than N and N is greater than 1;
means for receiving the N serial digital input signals which have transmitted therein symbols with a bit width M such that each of the N serial digital input signals transmits a fraction of the respective symbol; and
means for driving the plurality of bit storage devices cyclically such that at least M bits of the serial digital input signals, which belong to one symbol, are stored in the bit storage devices within a cycle.

19. A method of parallelizing N serial digital input signals, the method comprising:
supplying the N serial digital input signals to at least M bit storage devices including transmitting symbols with a bit width M via the N serial digital input signals such that each of the N serial digital input signals transmits a fraction of the respective symbols;
storing one bit of the N serial digital input signals respectively in each bit storage device;
allocating each bit storage device to one bit position of the symbol;
cyclically driving the at least M bit storage devices, where driving one of the at least M bit storage devices causes a data bit, which is supplied to the respective bit storage device, to be stored in the respective bit storage device such that at least M bits of the serial digital input signals, which belong to a symbol, are stored in the at least M bit storage devices within a cycle; and
reading the at least M bit storage devices to provide a parallel digital output signal with a bit width M, wherein M is greater than N and N is greater than 1

20. The method according to claim 19, wherein N is equal to 4.

21. The method according to claim 19, wherein M is equal to 9.

22. The method according to claim 19, wherein supplying the N serial digital input signals to at least M bit storage devices comprises:
selectively transmitting data bits for the bit position of the respective bit storage device to the respective bit storage devices.

23. The method of claim 23 wherein the selectively transmitting is performed with a plurality of multiplex devices each including an input side configured to receive a plurality of the N serial digital input signals and an output side coupled to an input of at least one of the bit storage devices.

24. A computer system comprising:
a central processing unit;
a memory arrangement connected to the central processing unit, wherein the memory arrangement and/or the central processing unit comprise:
an interface configured to transmit data and commands in the form of data packets according to a predetermined protocol between the central processing unit and the memory arrangement, the interface comprising a device configured to parallelize N serial digital input signals, the device comprising:
a plurality of bit storage devices configured to each respectively store one bit of the N serial digital input signals and provide the one stored bit as a bit of a parallel digital output signal with a bit width M, wherein M is greater than N, N is greater than 1, and the number of bit storage devices is at least M;
wherein symbols with a bit width M are transmitted via the N serial digital input signals such that each of the N serial digital input signals transmits a fraction of the respective symbol; and
a control device configured to drive the plurality of bit storage devices cyclically such that at least M bits of the serial digital input signals, which belong to one symbol, are stored in the bit storage devices within a cycle.

25. The computer system according to claim 24, wherein each of the bit storage devices is allocated to precisely one bit position of the symbol, wherein the device comprises:
a plurality of multiplex devices each including an input side configured to receive a plurality of the N serial digital input signals and an output side coupled to an input of at least one of the bit storage devices and together are configured to supply the serial digital input signals, which transmit data bits for the bit position of the respective bit storage device, selectively to the respective bit storage devices, wherein the control device is configured to drive the plurality of multiplex devices.
